(19) United States
(12) Patent Application Publication
(10) Pub. No.: US 2005/0146369 A1
(43) Pub. Date: Jul. 7, 2005

(54) Booster circuit

(76) Inventors: Ralf Gottsche, Munich (DE); Manuel Low, Munich (DE)

Correspondence Address: BRINKS HOFER GILSON & LIONE, P.O. BOX 10395, CHICAGO, IL, 60610, US

(21) Appl. No.: 10/977,311

(22) Filed: Oct. 29, 2004

(30) Foreign Application Priority Data
Oct. 29, 2003 (DE) 130 50 337.4

(51) Int. Cl. H03L 5/00

(52) U.S. Cl. 327/333

(57) ABSTRACT

Booster circuit (2), to which a first (3) and a second (4) signal are fed, wherein the booster circuit (2) is designed in such a way that it amplifies a voltage difference between the first (3) and the second (4) signal. Therefore, two output signals which are inverted with respect to one another, of a circuit section connected to the booster circuit (2) are amplified without loss of running time, a smaller additional area being required in comparison to conventional circuit variants.

The present invention relates to a booster circuit, such as can be used, in particular, in integrated circuits in clocked dynamic circuit technology (for example DDCVS circuit technology) for boosting signals.

“Domino Differential Cascode Voltage Switch” circuit technology (DDCVS circuit technology) is suitable as clocked dynamic circuit technology for implementing complex basic functions, such as, for example, a partial product former, summation former, carry former and an AND-OR-XOR function. In the process, these complex basic functions are generally implemented as single-stage cells in each case.

FIG. 1 shows a circuit section 1 with the function of a single-stage partial product former in DDCVS circuit technology as an example of a cell of this type. Apart from the supply voltages or supply potentials V_{SS} and V_{DD}, input signals 11 to 20 and a clock signal 5 are fed to this circuit section. During a precharging phase, in which the clock signal is at the supply potential V_{SS}, i.e. the clock pulse is not applied, an evaluation transistor 47 is switched off. Since, as mentioned, the clock signal 5 is at V_{SS}, two PMOS transistors 31, 34 are connected, so a first output signal 3 and a second output signal 4 of the circuit section 1 are charged to V_{DD}. During an evaluation phase, in which the clock signal 5 is at the supply potential V_{DD}, i.e. the clock pulse is not applied, according to the logical state of an NMOS network 61, which consists of NMOS transistors 35 to 46, one of the two output signals 3, 4 is discharged or drawn to V_{SS}, while the respective other output signal 4, 3 is either drawn to or held at V_{DD} via a PMOS transistor 32 or via a PMS transistor 33.

In the example shown, the NMOS network 61, as indicated above, forms a function of a single-stage partial product former (ppb) for a Booth multiplier. In this instance, the input signals 11 to 20 are linked to the output signal 3 according to a configuration of the transistors 35 to 46 shown in FIG. 1, wherein the following function is implemented where, with a constraint, z·z₂=0:
ppb=((x₁·z)+(x₀·z₂))·s_{—}n+(x₁_{_{—}}n·z+z_{—}n·(x₀_{_{—}}n+z₂_{_{—}}n))·s

In this instance, the following relationships for the reference numerals in FIG. 1 apply:

x₀ 13, x₀_{_{—}}n 14, x₁ 15, x₁_{_{—}}n 16, z 17, z_n 18, z₂ 19, z₂_{_{—}}n 20, s 11, s_n 12, ppb 3, ppb_n 4,

wherein a suffix “_n” stands for an inversion in each case, i.e. x₀_{_{—}}n is, for example, the inverted x₀.

The more complex the function to be produced, the more transistors are generally connected in series in the NMOS network 61. In the example shown in FIG. 1, four NMOS transistors are connected in series, including the evaluation transistor 47. In order to obtain an adequate driver capacity for discharging the output signals 3, 4, according to the prior art there is the possibility of dimensioning the transistor widths of the transistors 35 to 46 in the NMOS network so as to be correspondingly large. As a rule of thumb, the driver capacity of four transistors connected in series with quadruple channel width approximately corresponds to the driver capacity of a single transistor with a single channel width. In the process, the driver capacity of a single transistor with a single channel width is also called the basic driver strength.

In order for the circuit section 1 shown in FIG. 1 to produce a basic driver strength, all twelve transistors 35 to 46 of the NMOS network 61 and the evaluation transistor 47 have to be dimensioned with the quadruple channel width.

When the output load of a circuit section 1 of this type is large, the circuit section 1 has to have a high basic driver strength, in order to be able to reload the load within a predetermined time. Because the NMOS network 61 of any circuit section 1 generally has many transistors (twelve in the example) and each of these transistors has to have a multiple channel width (factor four in this example), in order to ensure the required driver capacity, the area requirement of a circuit section of this type in the layout of a microelectronic circuit is very large and increases according to a required driver capacity.

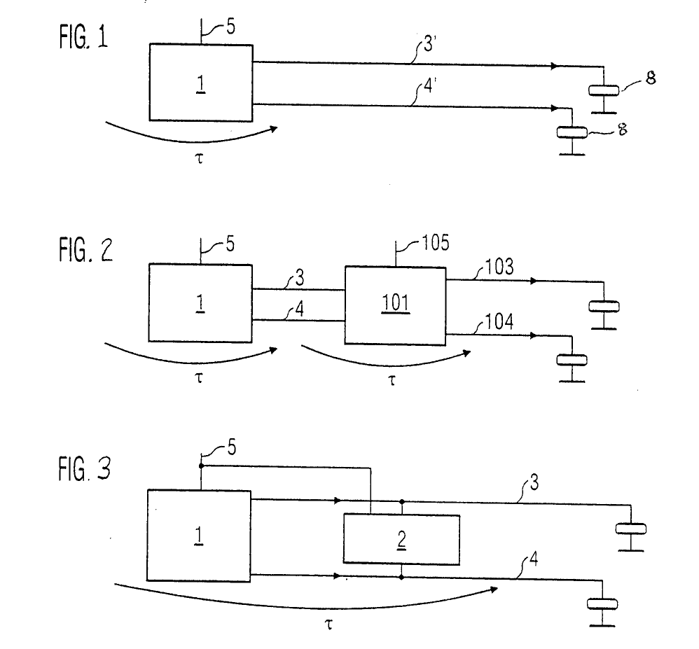

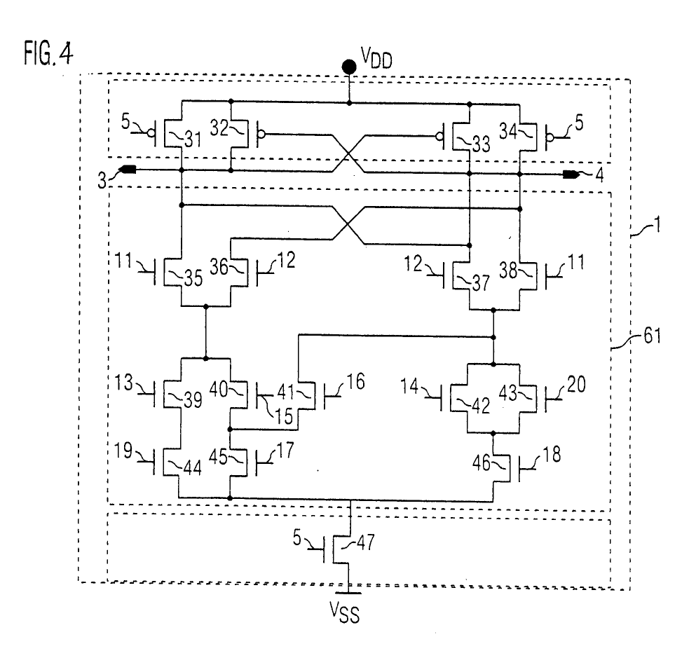

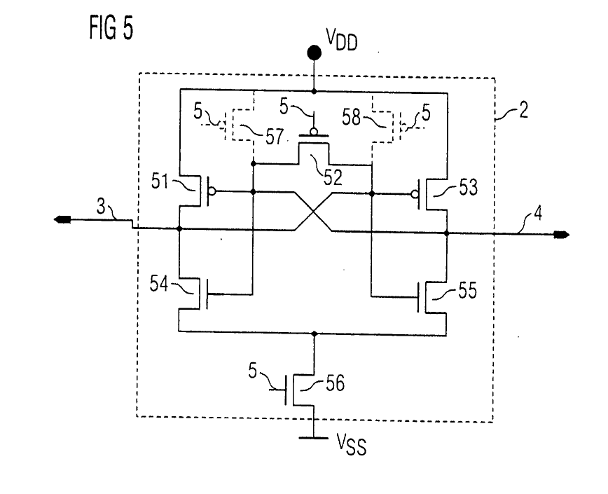

FIG. 2 schematically shows the circuit section 1 shown in FIG. 1, the output signals being denoted by reference numerals 3′ or 4′, in order later to be able to better differentiate the output signals of the circuit variant shown in FIG. 2 from the output signals 3, 4 of a different circuit variant shown in FIG. 4. The output signals 3′, 4′ of the circuit variant shown in FIG. 2 each drive an output load shown schematically by a capacitor. As a basis for comparison with other circuit variants, it is assumed that the channel width of the NMOS transistors of the circuit section 1 in FIG. 2 are increased tenfold compared to the normal case, so a sum of all transistors widths of 96 μm is produced as a measure for the area requirement. The running time over the circuit section 1 is then τ, which is identified in FIG. 2 by the corresponding arrow.

In order to increase the driver capacity of the circuit section 1, apart from the above-mentioned possibility of increasing the channel width of transistors, there is the possibility of inserting a driver cell 101 at the output of the circuit section 1, as shown in FIG. 3. In the process, a first output signal 103 of the driver cell 101 is the first output signal 3 of the circuit section 1 amplified by the driver cell 101 and a second output signal 104 is the second output signal 4 of the circuit section 1 amplified by the driver cell 101. In this circuit variant, the channel width of the transistors 35 to 47 can be selected so as to be small in the circuit section 1, as the increase in the driver capacity is achieved by the driver cell 101.

In order to achieve the same driver capacity as in the circuit variant shown in FIG. 2, the sum of all transistor widths is only 39 μm, however the running time has doubled (2*τ) and this is to be expressed by the two arrows designated by “τ”. The extension of the running time results, on the one hand, from the fact that the output signals 3, 4 of this circuit section have to run through the driver cell 101. On the other hand the driver cell 101 has to be triggered by an evaluation signal or clock signal 105, which is delayed compared to the clock signal 5 of the circuit section 1, so a delay or longer running time of the output signals 103, 104 of the driver cell 101 is produced.

The feeding of the clock signal 105 to the driver cell 101, is in itself a drawback, as, for example, in comparison to the circuit variant shown in FIG. 2, an additional clock signal 105 is required.

For this reason, an object of the present invention is to provide a circuit variant, which allows large loads to be driven, but in the process optimises the running time and/or the area requirement in comparison to known circuit variants.

A further object of the present invention is to provide a circuit variant for driving large loads, wherein, in comparison to known circuit variants with constant running time and area requirement, the dissipated power is reduced.

These objects are achieved by a booster circuit according to claim 1. The dependent claims define preferred and advantageous embodiments of the invention.

The booster circuit has a first signal connection, which is to be connected to a signal line conducting a first signal, and a second signal connection, which is to be connected to a signal line conducting a second signal. In the process, the booster circuit is designed in such a way that it amplifies a voltage difference between the first signal and the second signal at the first and second signal line in that it draws the first signal to a first potential which differs from a potential of the first signal and/or draws the second signal to a second potential which differs from a potential of the second signal.

While the voltage difference between the first and the second signal at the first and second signal line is amplified, and, for example, a driver cell does not amplify the two signals, in that the two signals run through this driver cell where they are amplified, as is conventional in the prior art (see, for example, FIG. 3), a running time advantage is produced in accordance with the invention as the running time is saved by the driver cell, or, in other words, no additional running time is caused by the use of the booster circuit.

The booster circuit can amplify this voltage difference between the first signal and the second signal in that it draws the second signal to a first potential (for example a supply potential V_{SS}) when a voltage difference between the first signal and this first potential is greater than a voltage difference between the second signal and this first potential. Accordingly, the booster circuit can amplify the voltage difference, in that it draws the first signal to the first potential when a voltage difference between the second signal and the first potential is greater than a voltage difference between the first signal and the first potential. This assumes, however, that the first potential is either at least as high as both the potential of the first signal and the potential of the second signal or at least as low as both the potential of the first signal and the potential of the second signal. In other words, the first potential should not lie “between” the potentials of the two signals, which is automatically fulfilled if, as already noted above, the first potential is a supply potential.

In accordance with the invention, the signal (either the first or the second signal) is therefore drawn to the first potential, the potential of which lies closer to this first potential. A circuit arrangement of this type is, in particular, advantageous when, on the one hand, the first signal is inverted with respect to the second signal, and, on the other hand, the first potential is the potential at which the first or the second signal would charge or discharge even without a booster circuit.

In the process, the first or the second signal is preferably only drawn to the first potential when a clock pulse, which is fed to the booster circuit, is applied.

As the booster circuit only draws the first or the second signal to the first potential when a clock pulse is applied, the booster circuit does not change the potential of the first or second signal when no clock pulse is applied. This is advantageous when the two signals are output signals of a clocked circuit arrangement connected to the booster circuit. In this constellation, the two signals, if no clock pulse is applied, have an undefined or irrelevant value (potential), so an amplification of the voltage difference between the two signals during a phase in which the clock pulse is not applied, would not be sensible or would be disadvantageous.

In addition, the booster circuit can be designed in such a way that it draws (precharges) the first and/or the second signal to a second potential (a supply potential) if a further clock signal is not applied. In the process, the further clock signal may correspond to the clock pulse described above. In a similar manner to the case with the first potential, this again assumes, however, that the second potential is either at least as high as both the potential of the first signal and also the potential of the second signal or is at least as low as both the potential of the first signal and the potential of the second signal, which is fulfilled, for example, when the second potential is the supply potential V_{DD}.

Precharging to the second potential is advantageous, in particular when this second potential corresponds to a potential to which the first or the second signal were charged or discharged even without the presence of the booster circuit when the clock pulse is applied. Moreover, the precharging to the second potential is advantageous if the booster circuit cooperates with a circuit arrangement which also precharges the two signals to the second potential.

However, the booster circuit may also be designed in such a way that it compensates a voltage difference between the first and the second signal, when a further clock pulse, which may correspond to the previously described clock pulse, is not applied.

Compensating the voltage difference between the first and the second signal is advantageous, in particular, when the booster circuit cooperates with a circuit arrangement which precharges the two signals, for example, to the second potential. Due to compensation of the voltage difference, which can be implemented in that the two signals are connected virtually without resistance via a circuit unit (for example a transistor) when the previously described further clock pulse is not applied, the charging of the two signals is assisted by the mentioned circuit arrangement.

In addition, the booster circuit can draw the second signal to the second potential when a voltage difference between the first signal and the second potential is greater than a voltage difference between the second signal and the second potential, in order to draw the first signal to the second potential when a voltage difference between the second signal and the second potential is greater than a voltage difference between the first signal and the second potential. In a similar manner to that described above repeatedly, this again assumes, however, that the second potential is either at least as high as both the potential of the first signal and the potential of the second signal or at least as low as both the potential of the first signal and the potential of the second signal, which is fulfilled, for example when the second potential is the supply potential V_{DD}.

In a similar manner to that described for the first potential, in accordance with the invention, the signal (either the first or the second signal) is drawn to the second potential, the potential of which lies closer to this second potential. A circuit arrangement of this type is advantageous, in particular, when, on the one hand, the first signal is inverted with respect to the second signal, and on the other hand, the second potential is the potential to which the first or the second signal is charged or discharged even without a booster circuit.

It should be pointed out that the previously described features with respect to the amplification of a voltage difference by drawing to the first potential, and with respect to the amplification of a voltage difference, by drawing to the second potential are independent of one another in principle and contribute separately in each case to achieving said objects.

As already mentioned above in the description of some advantages in accordance with the invention, the booster circuit may be connected to a circuit section from which a first and a second output signal can be picked up, in such a way that the first output signal is connected to the first signal and the second output signal is connected to the second signal of the booster circuit. In the process, at least one input signal can be fed to the circuit section, the circuit section determining the first output signal as a function of the at least one input signal and determining the second output signal inversely to the first output signal.

In the process, the circuit section may be designed in such a way that a clock signal (clock pulse) can be fed to it, and in that if the clock pulse is not applied, it draws the first and the second output signal to a second supply potential which corresponds to the second potential, and in that only if the clock pulse is applied, it determines the first output signal as a function of the at least one input signal. In the process, the clock signal of the circuit section may be equal to the clock signal of the booster circuit. Furthermore, both the circuit section and the booster circuit can be constructed with transistors.

In accordance with the invention, the transistors of the booster circuit may be designed in such a way that a driver capacity of a circuit arrangement consisting of the circuit section and the booster circuit can be selected virtually as desired, without the transistors of the circuit section being changed. This has the decisive advantage that the transistors of the circuit section can be designed to be small or space saving, without the driver capacity of the circuit arrangement being limited thereby. It is therefore possible for the circuit arrangement to drive large loads, without having to accept lengthening of the running time, in that only the booster circuit is set up or dimensioned accordingly.

In order for the circuit arrangement to be able to drive large loads, in accordance with the invention, the channel width of the transistors of the booster circuit can be extended according to the required driver capacity of the circuit arrangement. A further possibility of increasing the driver capacity of the circuit arrangement is to dynamically reduce the threshold voltage of the respectively connected transistors of the booster circuit, for example by substrate control.

The present invention is suitable, for example, for use in integrated circuits, which are constructed in clocked dynamic circuit technology, in particular the DDCVS circuit technology, in order to be used in high speed communication applications (line cards, network processors). Obviously, the invention is not limited, however, to this application area, but may, for example, also be used in circuits constructed with bipolar transistors or in non-microelectronic circuits.

The present invention will be described in more detail hereinafter with the aid of a preferred embodiment and with reference to the accompanying drawings, in which:

FIG. 1 shows a circuit section, which can be connected, in accordance with the invention, to a booster circuit.

FIG. 2 shows a circuit section with enlarged transistor widths without a booster circuit.

FIG. 3 shows a circuit section with a driver cell connected to the output.

FIG. 4 shows a circuit arrangement in accordance with the invention with a circuit section and a booster circuit.

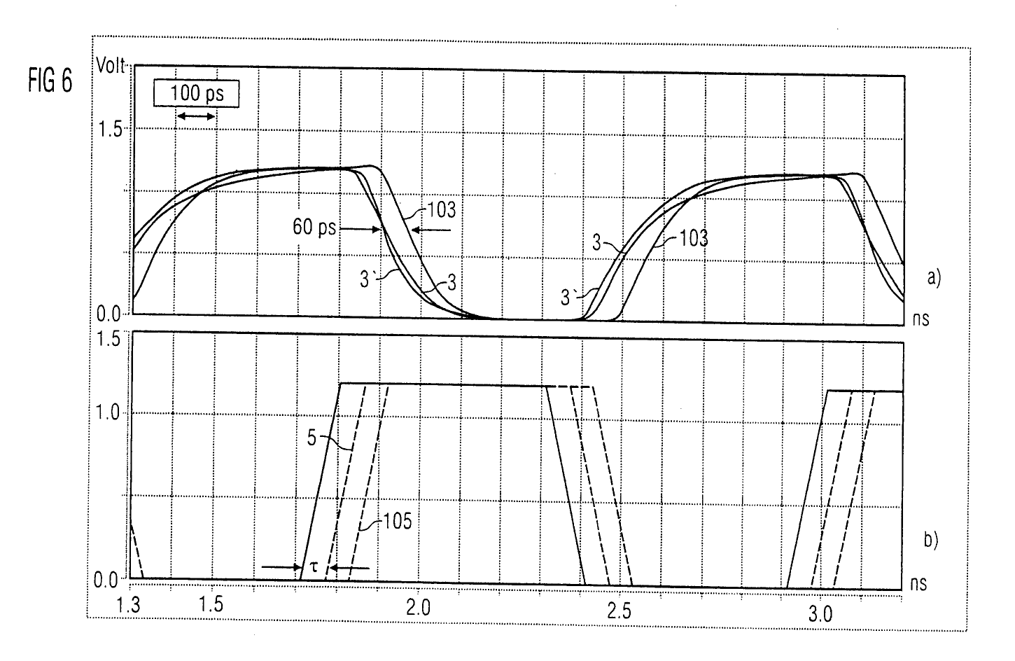

FIG. 5 shows an embodiment of the booster circuit in accordance with the invention.

FIG. 6 shows the course over time of output signals of the circuit variants shown in FIGS. 2 to 4.

As FIGS. 1 to 3 have already been described above, further description is dispensed with here and reference is made to the above description.

FIG. 4 shows an embodiment of a particular advantageous circuit arrangement, in which output signals, 3, 4 of a circuit section 1 are accordingly connected to a booster circuit 2, wherein the circuit section 1 and the booster circuit 2 in this embodiment operate with the same clock signal 5.

In the process, the booster circuit 2 is designed in such a way that it amplifies the voltage difference between the output signals 3, 4. It will be shown hereinafter how this configuration appears in detail.

As the booster circuit 2 operates with the same clock signal 5 as the circuit section 1, no additional evaluation signal or clock signal is required. For this reason and as the output signals 3, 4 do not run through the booster circuit 2, the booster circuit 2 does not need any additional running time and does not impair the timing.

In the case of the conditions selected in one example, the area requirement of the transistors for the circuit section 1 and the booster circuit 2 in the circuit variant shown in FIG. 4 is about 15% more than the area requirement of the transistors for the circuit section 1 and the driver cell 101 in the circuit variant shown in FIG. 3. However, the latter circuit variant (FIG. 3), in the conditions selected, as mentioned, requires twice the running time. Differences in running time will be dealt with in more detail hereinafter with respect to FIG. 6.

A further advantage of the circuit variant shown in FIG. 4 is that the entire parasitic capacity of the circuit section 1 and the booster circuit 2 is reduced in comparison to other circuit variants, thereby reducing dissipated power.

The construction of the booster circuit 2 shown in FIG. 4 is shown in FIG. 5 with the aid of a possible embodiment, where it is assumed that the booster circuit 2 shown in FIG. 5 is connected to a circuit section 1, as shown in FIG. 4. In other words that a signal line conducting the first output signal 3 of the circuit section 1 (see FIG. 1) is connected to a first signal connection of the booster circuit 2 and a signal line conducting the second output signal 4 of the circuit section 1 is connected to a second signal connection of the booster circuit 2. In this instance, the first output signal 3 corresponds to a first signal 3 and the second output signal 4 corresponds to a second signal 4, so hereinafter, as an abbreviation, the first signal 3 and second signal 4 will be mentioned instead of the first and second output signal.

During a precharging phase, an NMOS evaluation transistor 56 is switched off by the clock signal 5 (clock pulse 5 is not applied or the clock signal is at V_{SS}). The first signal 3 and second signal 4 are precharged to a supply potential V_{DD} via the connected circuit section 1. A PMOS transistor 52 assists this precharging, in that it ensures charging compensation between the first signal 3 and the second signal 4.

Shortly before the start of an evaluation phase, the two signals 3, 4 are therefore at V_{DD}, which means that a PMOS transistor 51 and a PMOS transistor 53 are switched off and an NMOS transistor 54 and an NMOS transistor 55 are connected, as the gate connection of these four transistors 51, 53 to 55 is connected in each case to one of the two signals 3, 4. At the beginning of the evaluation phase (clock pulse 5 is applied or clock signal 5 is at V_{DD}), the evaluation transistor 56 becomes conductive, so a first path, which is defined by the NMOS transistor 54 and the evaluation transistor 56 and connected to the first signal 3, and a second path, which is defined by the NMOS transistor 55 and the evaluation transistor 56 and connected to the second signal 4, also become conductive, so the two signals 3, 4 are (briefly) drawn in the direction V_{SS} 7.

However, as the connected circuit section 1, at the beginning of the evaluation phase, begins to draw either the first 3 or the second signal 4 in the direction V_{SS}, either the transistor 54, when the second signal 4 is drawn by the circuit section 1 in the direction V_{SS}, or the transistor 55, if the first signal 3 is drawn by the circuit section 1 in the direction V_{SS} is more limited than the respective other transistor 54; 55, as the gate connection of the transistor 54 is connected to the second signal 4 and the gate connection of the transistor 55 is connected to the first signal 3. Therefore, either the first path or the second path becomes a poorer conductor than the other. Depending on which path becomes the poorer conductor, one of the two signals 3; 4 is drawn less strongly in the direction V_{SS} or, after the shortest time, not drawn at all in the direction V_{SS} when the corresponding transistor 54; 55 is completely limited, while the respective other signal 4; 3 continues to be drawn to V_{SS} as at the beginning of the evaluation phase until completely discharged.

Advantageously, the signal 4; 3 continues to be drawn to V_{SS} by the booster circuit 2, which signal was drawn to V_{SS} at the beginning of the evaluation phase by the circuit section 1. Advantageously, a small voltage difference, which was initially only brought about slowly by the circuit section 1, is therefore amplified between the two signals 3; 4.

According to the same plan, as in the case of the NMOS transistors 54, 55, the first signal 3 is connected to V_{DD} via the PMOS transistor 51 and the second signal 4, via the PMOS transistor 53. In the process, the gate connection of the transistor 51 is connected to the second signal 4 and the gate connection of the transistor 53 to the first signal 3. As the two signals 3, 4, as described already, are at V_{DD} shortly before the beginning of the evaluation phase, the two PMOS transistors 51, 53 are blocked, as already described above.

However, as at the start of the evaluation phase, the circuit section 1, in addition to the booster circuit 2, that, as described, draws the two signals 3, 4 in the direction V_{SS} at the beginning of the evaluation phase, begins to draw one of the signals 3; 4 to V_{SS}, one of the transistors 51; 53 becomes more conductive than the respective other 53; 51. In an advantageous manner, this is the transistor 51; 53 which is connected to the signal 3; 4 which is not also drawn in the direction V_{SS} by the circuit section 1, but is left at or drawn to V_{DD} by the circuit section 1. Therefore, advantageously, the signal 3; 4 which is left at or drawn to V_{DD} by the circuit section 1, is now also drawn by the booster circuit 2 to V_{DD}, whereby the voltage difference between the two signals 3, 4 initially only brought about by the circuit section 1 is further amplified.

In the steady state, the booster circuit 2 draws the signal 3; 4 to V_{SS}, which is also drawn by the circuit section 1 to V_{SS}, and draws the signal 4; 3 to V_{DD}, which is also left at or drawn to V_{DD} by the circuit section 1. Therefore one of the PMOS transistors 53; 51 is conductive, while the respective other PMOS transistor 51; 53 blocks. In the same way, one of the NMOS transistors 53; 54 is conductive, while the respective other NMOS transistor 55; 54 blocks. Advantageously, the PMOS transistor 53; 51, of which the signal 4; 3 connected to the drain connection is at V_{DD}, is conductive. In the same way, the NMOS transistor 54; 55, to the drain connection of which the signal 3; 4 at V_{SS} is connected, is conductive. Therefore the steady state is extremely stable.

It should be noted that the booster circuit 2 would also operate advantageously if the PMOS transistors 51, 53 were not present. Furthermore, the PMOS transistor 52 could also, or additionally, be dispensed with without losing the basic functionality of the booster circuit 2.

Furthermore, in addition to the PMOS transistor 52, a further PMOS transistor 57, 58 could be present which precharges either the first 3 or the second 4 signal to V_{DD} 8 in the precharging phase. This further PMOS transistor 57, 58 could be connected with its drain connection either to the first 3 or the second 4 signal and with its source connection to V_{DD}. So that the first 3 or second 4 signal is then only precharged to V_{DD} by this further PMOS transistor 57, 58, when the booster circuit 2 is in the precharging phase, the gate connection of the further PMOS transistor 57, 58 is connected to the clock signal 5.

In a further embodiment, instead of the PMOS transistor 58 (or in addition to the PMOS transistor 52) two further PMOS transistors 57, 58 could be present to be able to precharge the two signals 3, 4 in the precharging phase to V_{DD} even without a connected circuit section. In the process, the drain connection of the first further PMOS transistor 57 would be connected to the first signal 3 and the drain connection of the second further PMOS transistor 58 to the second signal 4. The source connection of both the first 57 and the second 58 further PMOS transistor would be connected to V_{DD}. For the same reason as in the first embodiment with a further PMOS transistor, the gate connections of the two further PMOS transistors are connected to the clock signal 5, so that the two signals 3, 4 are only charged to V_{DD} when the booster circuit 2 is in the precharging phase.

While the booster circuit 2 of the embodiment is constructed with NMOS and PMOS transistors, there are also embodiments of the booster circuit which are constructed with transistors which all have the same conductivity type (for example only NMOS transistors or only bipolar transistors). Furthermore, embodiments are conceivable, in which the conductivity types of the transistors are distributed differently than in the embodiments described above in detail. For example, certain PMOS transistors 51 to 53, 57, 58 could also be designed as NMOS transistors, while certain NMOS transistors 54 to 56 could also be designed as PMOS transistors, wherein, in these cases, in certain circumstances, a further clock signal is required which is preferably inverted with respect to the available clock signal 5.

The circuit variants shown in FIGS. 2 to 4 will now be examined in more detail with respect to their running time with the results of a circuit simulation.

In this instance, the following prerequisites apply. The loads to be driven by each circuit variant and which are shown schematically in FIGS. 2 to 4 by a capacitor in each case, are the same. The transistor widths of the circuit variant shown in FIG. 2 were established at ten times a normal transistor width, so an area requirement, which is measured as the sum of the transistor width of the transistors used, of 96 μm was produced. Twice the transistor width was set for the transistors in the circuit section 2 of the circuit variant shown in FIG. 3 and FIG. 4, in each case. On the other hand, an eight-fold transistor width was assumed as the transistor width for the transistors of the driver cell 105 and the transistors of the booster circuit 2, in each case. This produced an area requirement of 39 μm, again measured in the sum of the transistor widths, for the circuit variant in FIG. 3 and of 45 μm for the circuit variant in FIG. 4.

FIG. 6b shows the course over time of the clock signals 5, 105 required for the three circuit variants. The clock signal, not shown, is used here in the simulation to trigger the periphery and has no influence on the interconnections.

FIG. 6a shows the course over time of the output signals 3, 3′, 103 of the three circuit variants, these being loaded respectively with the clock signals 5, 105 shown in FIG. 6b. It has been shown that the course over time of the output signal 3′ of the circuit variant of FIG. 2 is very similar to the course over time of the output signal 3 of the circuit variant of FIG. 4, in other words the running times of the two circuit variants are similar. It should be noted here that differences in timing of a few 10 ps in the circuit technology used can be compensated by optimisations. On the other hand, the difference in running time which can be seen from FIG. 6a between the output signal 103 of the circuit variant from FIG. 3 and the output signal 3 or 3′ of the circuit variants from FIG. 4 or FIG. 2 are significant in an order of magnitude of 60 ps.

To summarise, it can be stated with respect to the running times, that the circuit variants of FIGS. 2 and 4 exhibit similar running time behaviour, while the running time behaviour of the circuit variant of FIG. 3 falls significantly in comparison.

A comparison of the area requirement of the circuit variants already described above shows that the two circuit variants of FIGS. 3 and 4 have approximately the same area requirement (39 to 45 μm), whereas the circuit variant in FIG. 2 has twice the area requirement (96 μm) in comparison.

The use of the booster circuit 2 therefore leads to the smallest area requirement and simultaneously to the shortest running time.

1. Booster circuit, comprising
a first signal connection, which is to be connected to a signal line conducting a first signal, and
a second signal connection, which is to be connected to a signal line conducting a second signal,
wherein the booster circuit is designed in such a way that it amplifies a voltage difference between the first signal and the second signal at the first and second signal line in that it draws the first signal to a first potential differing from a potential of the first signal and/or draws the second signal to a second potential differing from a potential of the second signal.

2. Booster circuit according to claim 1,
wherein the booster circuit amplifies the voltage difference, when a voltage difference between the first signal and the first potential is greater than a voltage difference between the second signal and the first potential, by drawing the second signal to the first potential while, if a voltage difference between the second signal and the first potential is greater than a voltage difference between the first signal and the first potential, it draws the first signal to the first potential,
wherein the first potential is either at least as high as both the potential of the first signal and the potential of the second signal or at least as low as both the potential of the first signal and the potential of the second signal.

3. Booster circuit according to claim 2,
wherein a clock signal is fed to the booster circuit, the booster circuit drawing the first or the second signal to the first potential only when the clock signal is applied.

4. Booster circuit according to claim 1,
wherein the booster circuit is designed such that it draws the first and/or the second signal in the interim to the second signal, the second potential being either at least as high as both the potential of the first signal and the potential of the second signal or at least as low as both the potential of the first signal and the potential of the second signal.

5. Booster circuit according to claim 4,
wherein a clock signal is fed to the booster circuit, the booster circuit being designed such that it only draws the first and/or the second signal to the second potential when the clock signal is not applied.

6. Booster circuit according to claim 1,
wherein a clock signal is fed to the booster circuit, the booster circuit being designed such that it compensates a voltage difference between the first and second signal, when the clock signal is not applied.

7. Booster circuit according to claim 1,
wherein the booster circuit amplifies the voltage difference, when a voltage difference between the first signal and a second potential is greater than a voltage difference between the second signal and the second potential, by drawing the second signal to the second potential, while, when a voltage difference between the second signal and the second potential is greater than a voltage difference between the first signal and the second potential, it draws the first signal to the second potential,
the second potential being either at least as high as both the potential of the first signal and the potential of the second signal or at least as low as both the potential of the first signal and the potential of the second signal.

8. Booster circuit according to claim 1,
wherein the booster circuit is constructed with transistors.

9. Booster circuit according to claim 1,
wherein the first potential is equal to a first supply potential of the booster circuit and/or the second potential is equal to a second supply potential of the booster circuit.

10. Booster circuit according to claim 9,
wherein the first signal connection is connected to a first connection of a first transistor and to a control connection of a second transistor, and
wherein the second signal connection is connected to a first connection of the second transistor and to a control connection of the first transistor,
the second connection of the first transistor and the second connection of the second transistor being connected to the first connection of a third transistor, the control connection of which is connected to a clock signal and the second connection of which is connected to the first supply potential.

11. Booster circuit according to claim 10,
wherein the first signal connection is connected to the first connection of a fourth transistor and a control connection of a fifth transistor, and
wherein the second signal connection is connected to a first connection of the fifth transistor and a control connection of the fourth transistor,
the second connection of the fourth transistor and the second connection of the fifth transistor being connected to the second supply potential.

12. Booster circuit according to claim 10,
wherein a further transistor is connected between the first signal connection and the second signal connection, a clock signal being applied at a control connection of the further transistor.

13. Booster circuit according to claim 10,
wherein the first signal connection is connected to a first connection of a further transistor, a control connection of the further transistor being connected to a clock signal, and
wherein a second connection of the further transistor is connected to the second supply potential.

14. Booster circuit according to claim 10,
wherein the second signal connection is connected to a first connection of a further transistor, a control connection of the further transistor being connected to a clock signal, and
wherein a second connection of the further transistor is connected to the second supply potential.

15. Booster circuit according to claim 10 and claim 11 and any one of claims 12-14,
wherein the first to third transistors are of a first conductivity type and the fourth and fifth transistors as well as the further transistor(s) are of a second conductivity type.

16. Booster circuit according to claim 15,
wherein the first conductivity type is NMOS and the second conductivity type is PMOS.

17. Circuit arrangement, comprising
a circuit portion, to which at least one input signal can be fed and from which a first and a second output signal can be tapped off, the circuit section being designed in such a way that it determines the first output signal as a function of the at least one input signal and in that it determines the second output signal inversely to the first output signal,
wherein the circuit arrangement has a booster circuit according to any one of claims 1 to 16, the first output signal of the circuit section being connected to the first signal connection of the booster circuit and the second output signal of the circuit section being connected to the second signal connection of the booster circuit.

18. Circuit arrangement according to claim 17,
wherein a clock signal can be fed to the circuit section, and
wherein the circuit section is designed in such a way that, if the clock signal is not applied, it draws the first and second output signal to a supply potential, while it determines the first output signal as a function of the at least one input signal only if the clock signal is applied.

19. Circuit arrangement according to claim 17,
wherein the clock signal of the circuit section is equal to a clock signal of the booster circuit.

20. Circuit arrangement according to claim 17,
wherein the circuit section and the booster circuit are constructed with transistors, channel widths of the transistors of the booster circuit being greater than channel widths of the transistors of the circuit section.

21. Circuit arrangement according to claim 17,
wherein the booster circuit is constructed with transistors and is designed in such a way that means are provided for lowering a threshold voltage of those transistors of the booster circuit, which are to be turned on respectively, relative to a threshold voltage of the transistors of the circuit section.

22. Circuit arrangement according to claim 17,
wherein the circuit section and/or the booster circuit are/is constructed by DDCVS circuit technology.
